(19) United States
(12) Patent Application Publication
(10) Pub. No.: US 2010/0327465 A1
(43) Pub. Date: Dec. 30, 2010

(54) PACKAGE PROCESS AND PACKAGE STRUCTURE

(75) Inventors: CHI-CHIH SHEN, Kaohsiung City (TW); Jen-Chuan Chen, Taoyuan County (TW); Tommy Pan, Taipei City (TW)

Correspondence Address: J C PATENTS, 4 VENTURE, SUITE 250, IRVINE, CA, 92618, US

(73) Assignee: Advanced Semiconductor Engineering, Inc., Kaohsiung (TW)

(21) Appl. No.: 12/538,338

(22) Filed: Aug. 10, 2009

(30) Foreign Application Priority Data
Jun. 25, 2009 (TW) 98121414

(51) Int. Cl. H01L 23/31; H01L 21/60

(52) U.S. Cl. 257/778; 438/108; 257/E21.511; 257/E23.129

(57) ABSTRACT

A package process is provided. First, a semiconductor substrate is disposed on a carrier, in which a surface of the carrier has an adhesive layer and the semiconductor substrate is bonded to the carrier by the adhesive layer. Next, a chip is bonded on the semiconductor substrate by flip chip technique and a first underfill is formed between the chip and the semiconductor substrate to encapsulate a plurality of first conductive bumps at the bottom of the chip. Then, a first molding compound is formed on the semiconductor substrate. The first molding compound at least encapsulates the side surface of the chip and the first underfill. Finally, the semiconductor substrate together with the chip and the first molding compound located thereon are separated from the adhesive layer of the carrier to form an array package structure.

### CROSS-REFERENCE TO RELATED APPLICATION

This application claims the priority benefit of Taiwan application serial no. 98121414, filed on Jun. 25, 2009. The entirety of the above-mentioned patent application is hereby incorporated by reference herein and made a part of this specification.

### BACKGROUND OF THE INVENTION

1. Field of the Invention

The present invention relates to a semiconductor process and a structure thereof, and more particularly, to a package process and a package structure thereof.

2. Description of Related Art

With recent advancement of semiconductors and packaging techniques, the fabrication of micro devices including micro-electromechanical devices or electro-optical devices is currently achieved by adopting a prevailing wafer packaging technique rather than a chip packaging technique. Thereby, packaging costs are reduced, and the requirements for lightweight, slimness, compactness, and small volume are satisfied. In details, the wafer level package focuses on packaging wafer to simplify the chip packaging process for saving time and costs. After the IC on the wafer is formed completely, the entire wafer is directly performed with the packaging process. Thereafter, the wafer sawing can be performed to form a plurality of chip packages respectively, and the chip packages manufactured are installed on the circuit substrate.

Generally, before fabricating the IC on the wafer, a thinning process is usually performed to the wafer for reducing the thickness of the wafer. The fabricating process of the IC on the wafer includes bonding a plurality of chips to each chip bonding region on the wafer correspondingly by the flip chip bonding technique. Since the process capacitance of bonding the chip to the wafer by using the flip chip bonding technique still has its limit value, when the thickness of the wafer used is smaller than the limit value of the process capacitance thereof, fracture often results in the flip chip bonding process, thereby reducing the production yield rate.

### SUMMARY OF THE INVENTION

The present invention is directed to a package structure having a thinner semiconductor substrate for reducing a thickness of the package.

The present invention is directed to a package process for fabricating a package structure aforementioned.

The present invention is directed to a package process. Firstly, a semiconductor substrate is disposed on a carrier. A surface of the carrier has an adhesive layer and the semiconductor substrate is bonded to the carrier by the adhesive layer. Next, a chip is bonded on the semiconductor substrate by a flip chip technique via a plurality of first conductive bumps at a bottom of the chip. Thereafter, a first molding compound is formed on the semiconductor substrate. The first molding compound at least encapsulates a side surface of the chip. Finally, the semiconductor substrate together with the chip and the first molding compound located thereon are separated from the adhesive layer of the carrier to form an array package structure.

In one embodiment of the present invention, in the aforementioned package process, the semiconductor substrate is further ground to reduce a thickness of the semiconductor substrate under 4 mils after the semiconductor substrate has been disposed on the carrier.

In one embodiment of the present invention, a first underfill is coated on the semiconductor substrate before bonding the chip and the semiconductor substrate to encapsulate the first conductive bumps at the bottom of the chip, and the first molding compound further encapsulates the first underfill.

In one embodiment of the present invention, a first underfill is filled between the chip and the semiconductor substrate after bonding the chip on the semiconductor substrate to encapsulate the first conductive bumps at the bottom of the chip, and the first molding compound further encapsulates the first underfill.

In one embodiment of the present invention, the first molding compound further encapsulates a top surface of the chip.

In one embodiment of the present invention, the first molding compound exposes the top surface of the chip.

In one embodiment of the present invention, after the carrier and the adhesive layer are removed, the array package structure is further cut to form a chip package unit. The chip package unit includes the chip and a substrate unit of the corresponding semiconductor substrate, wherein a side of the first molding compound substantially aligns with a side of the semiconductor substrate.

In one embodiment of the present invention, in the package process, the chip package unit is further bonded to a circuit substrate by the flip chip technique.

In one embodiment of the present invention, in the package process, a second molding compound is further formed on the circuit substrate and the second molding compound at least encapsulates a side surface of the chip package unit.

In one embodiment of the present invention, in the package process, a second underfill is further formed between the chip package unit and the circuit substrate to encapsulate a plurality of second conductive bumps at a bottom of the chip package unit.

In one embodiment of the present invention, the second molding compound further encapsulates a top surface of the chip package unit.

In one embodiment of the present invention, the second molding compound further exposes the top surface of the chip package unit.

A package structure including a semiconductor substrate, a chip, a first underfill, and a first molding compound is further provided in the present invention. The semiconductor substrate has an upper surface, where a thickness of the semiconductor substrate is under 8 mils. The chip is disposed on the upper surface of the semiconductor substrate and a bottom of the chip has a plurality of first conductive bumps. The first underfill is disposed between the semiconductor substrate and the chip to encapsulate the first conductive bumps. The first molding compound is disposed on the semiconductor substrate and at least encapsulates a side surface of the chip and the first underfill.

In one embodiment of the present invention, a thickness of the semiconductor substrate is under 4 mils.

In one embodiment of the present invention, the first molding compound further encapsulates a top surface of the chip.

In one embodiment of the present invention, the first molding compound exposes the top surface of the chip.

In one embodiment of the present invention, the package structure further includes a circuit substrate. The circuit substrate is disposed on a lower surface of the semiconductor substrate relative to the upper surface.

In one embodiment of the present invention, the package structure further includes a second molding compound. The second molding compound is disposed on the circuit substrate and at least encapsulates the first molding compound and a side face of the semiconductor substrate.

In one embodiment of the present invention, the package structure further includes a second underfill. The second underfill is disposed between the semiconductor substrate and the circuit substrate to encapsulate a plurality of second conductive bumps on the lower surface of the semiconductor substrate.

In one embodiment of the present invention, the second molding compound further encapsulates the chip and a top surface of the first molding compound.

In one embodiment of the present invention, the second molding compound exposes the chip and the top surface of the first molding compound.

In one embodiment of the present invention, the semiconductor substrate is a silicon substrate.

In one embodiment of the present invention, a side of the first molding compound substantially aligns with a side of the semiconductor substrate.

In light of the foregoing, since the thickness of the semiconductor substrate in the present invention is thinner (i.e. under 8 mils), when the chip is bonded on the semiconductor substrate by the flip chip technique and encapsulated by the molding compound to form the package structure, this package structure has a thinner package thickness. In addition, as the semiconductor substrate of the present invention is supported by the carrier, the fracture of semiconductor substrate during the flip chip bonding of the chip onto the semiconductor substrate is prevented. Furthermore, since the semiconductor substrate is first packaged by the molding compound and then cut, the strength of the semiconductor substrate is relatively enhanced to prevent the fracture of the semiconductor substrate so as to lower the difficulty in the subsequent process and facilitate in enhancing the production yield rate. Moreover, it is suitable for mass production.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a package structure according to an embodiment of the present invention.

FIG. 1B is a schematic cross-sectional view of a package structure according to another embodiment of the present invention.

FIG. 1C is a schematic cross-sectional view of a package structure according to another embodiment of the present invention.

FIG. 2 is a flow chart illustrating a manufacturing process of a package structure according to an embodiment of the present invention.

FIGS. 3A through 3G are schematic cross-sectional views illustrating a package process according to an embodiment of the present invention.

FIG. 4A through 4B are cross-sectional views illustrating a formation of a first underfill and a bonding of a chip according to another embodiment of the present invention.

FIG. 5A through 5B are schematic cross-sectional views illustrating formations of a first molding compound according to two different embodiments in the present invention.

FIG. 6A is a schematic cross-sectional view of flip chip bonding a chip package unit to a circuit substrate according to another embodiment of the present invention.

FIG. 6B is a schematic cross-sectional view of flip chip bonding the chip package unit to the circuit substrate according to another embodiment of the present invention.

### DESCRIPTION OF EMBODIMENTS

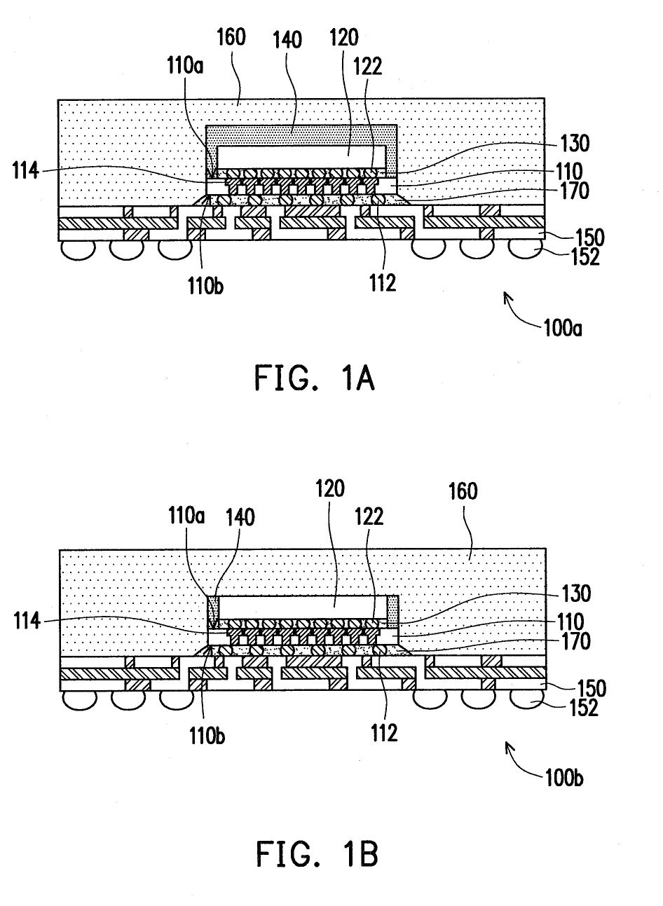

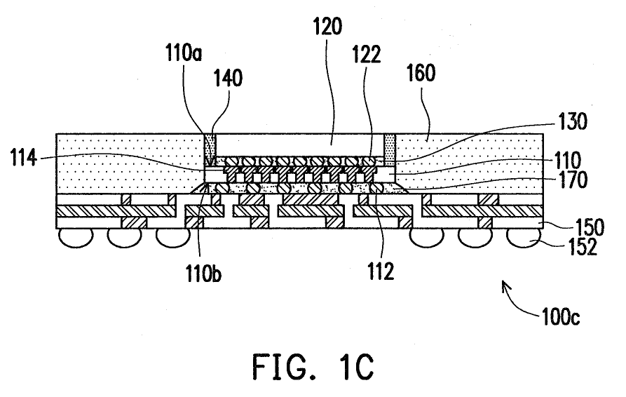

FIG. 1A is a schematic cross-sectional view of a package structure according to an embodiment of the present invention. Referring to FIG. 1A, a package structure 100a includes a semiconductor substrate 110, a chip 120, a first underfill 130, and a first molding compound 140.

The semiconductor substrate 110 is, for example, a silicon substrate and has an upper surface 110a. Here, a thickness of the semiconductor substrate 110 is under 8 mils, such as under 4 mils or even 2 mils. The chip 120 is disposed on the upper surface 110a of the semiconductor substrate 110 and a bottom of the chip 120 has a plurality of first conductive bumps 122. The first underfill 130 is disposed between the semiconductor substrate 110 and the chip 120 to encapsulate the first conductive bumps 122. The first molding compound 140 is disposed on the semiconductor substrate 110 and encapsulates a side surface of the chip 120, the first underfill 130, and a top surface of the chip 120. A side of the first molding compound 140 substantially aligns with a side of the semiconductor substrate 110.

It should be noted that in the present embodiment, the semiconductor substrate 110 adopts a through-silicon via (TSV) technique to electrically connect with the chip 120. Herein, in the TSV technique, a conductive channel is manufactured inside a chip or a wafer, for example, to form a perpendicular TSV structure 114, so that the chip 120 has a greatest density of stacking chips in three-dimensional directions and has a smallest configuration size. Therefore, a signaling between the semiconductor substrate 110 and the chip 120 is transmitted through the TSV structure 114 to enhance speed of devices, reduce signal delays, and suppress power consumptions.

Moreover, the package structure 100a of the present embodiment further includes a circuit substrate 150, a second molding compound 160, and a second underfill 170. The circuit substrate 150 is disposed on a lower surface 110b of the semiconductor substrate 110 relative to the upper surface 110a. A bottom of the circuit substrate 150 has a plurality of solder balls 152. Here, the circuit substrate 150 is a printed circuit board, for instance. The second molding compound 160 is disposed on the circuit substrate 150 and encapsulates side surfaces of the first molding compound 140 and of the semiconductor substrate 110, and a top surface of the first molding compound 140. The second underfill 170 is disposed between the semiconductor substrate 110 and the circuit substrate 150 to encapsulate a plurality of second conductive bumps 112 on the lower surface 110b of the semiconductor substrate 110.

It should be illustrated that in the present embodiment, the second underfill 170 is disposed between the semiconductor substrate 110 and the circuit substrate 150 to encapsulate the second conductive bumps 112 on the lower surface 110b of the semiconductor substrate 110. However, in other embodiments, the second underfill 170 is absent; that is, the second underfill 170 is not disposed between the semiconductor substrate 110 and the circuit substrate 150. The second conductive bumps 112 of the lower surface 110b of the semiconductor substrate 110 are encapsulated by the second molding compound 160. The aforesaid method would still be a part of the technical proposal of the present invention and not departing from the protection range of the present invention.

In addition, the present invention is not limited to locations and types of the first molding compound 140 and the second molding compound 160. Although the first molding compound 140 mentioned herein specifically encapsulates the side surface of the chip 120, the underfill 130, and the top surface of the chip 120, and the second molding compound specifically encapsulates at least the side surfaces of first molding compound 140 and of the semiconductor substrate 110, other structural designs known for protecting the chip 120 are still within the technical proposal of the present invention and not departing from the protection range of the present invention.

Two embodiments are described in the following to illustrate that the designs of the first molding compound 140 and the second molding compound 160 of two package structures 100b˜100c are different from the designs of the first molding compound 140 and the second molding compound 160 of the package structure 100a.

FIG. 1B is a schematic cross-sectional view of a package structure according to another embodiment of the present invention. Referring to FIG. 1B, in the present embodiment, the package structure 100b of FIG. 1B is similar to the package structure 100a of FIG. 1A. A major difference between the two is that the first molding compound 140 exposes the top surface of the chip 120 and the second molding compound 160 encapsulates the top surfaces of the chip 120 and of the first molding compound 140. Here, the side of the first molding compound 140 substantially aligns with the side of the semiconductor substrate 110.

FIG. 1C is a schematic cross-sectional view of a package structure according to another embodiment of the present invention. Referring to FIG. 1C, in the present embodiment, the package structure 100c of FIG. 1C is similar to the package structure 100a of FIG. 1A. A major difference between the two is that the first molding compound 140 exposes the top surface of the chip 120 and the second molding compound 160 also exposes the top surfaces of the chip 120 and of the first molding compound 140. Here, the side of the first molding compound 140 substantially aligns with the side of the semiconductor substrate 110. Since the first molding compound 140 and the second molding compound 160 both expose the top surface of the chip 120, a heat dissipation area and a performance of the chip 120 are enhanced. In other words, the package structure 100c has superior heat dissipation effect.

In short, the thickness of the semiconductor substrate 110 in the present embodiment is under 8 mils, such as under 4 mils or even 2 mils. Hence, when the chip 120 and the circuit substrate 150 are respectively disposed on the upper surface 110a and the lower surface 110b of the semiconductor substrate 110, and the first molding compound 140 and the second molding compound 160 encapsulate the chip 120, the semiconductor substrate 110, and the circuit substrate 150 to form the package structure 100a (or package structures 100b, 100c), this package structure 100a (or package structures 100b, 100c) has a thinner package thickness. Besides, when the first molding compound 140 exposes the top surface of the chip 120 and the second molding compound 160 also exposes the top surface of the chip 120, the heat dissipation area and performance of the chip 120 are enhanced, so that the package structure 100c has superior heat dissipation effect.

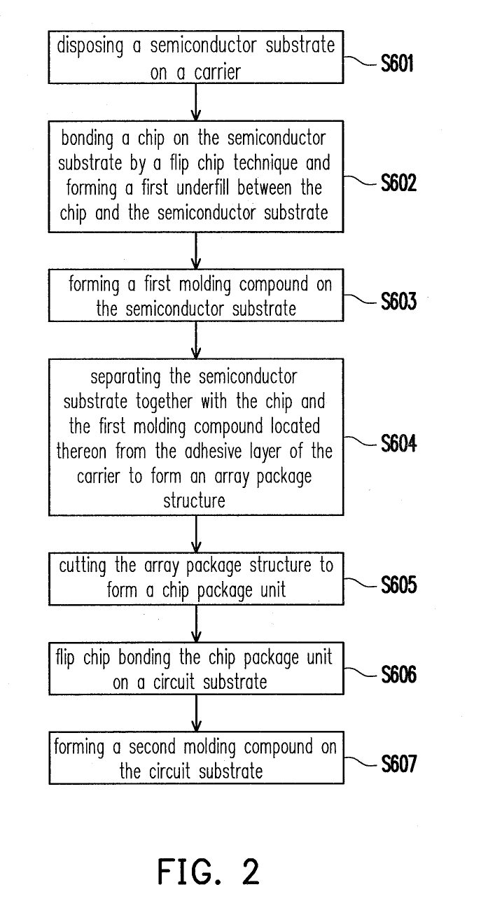

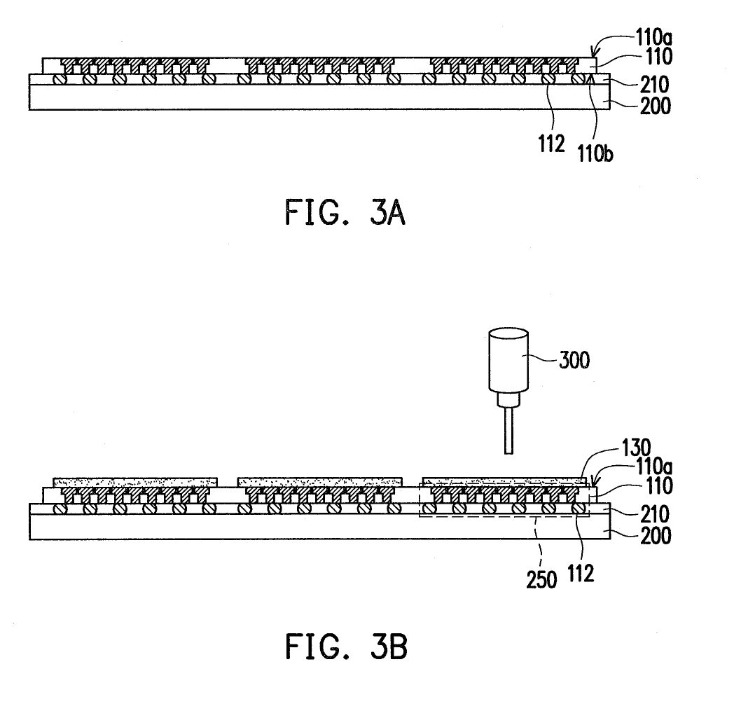

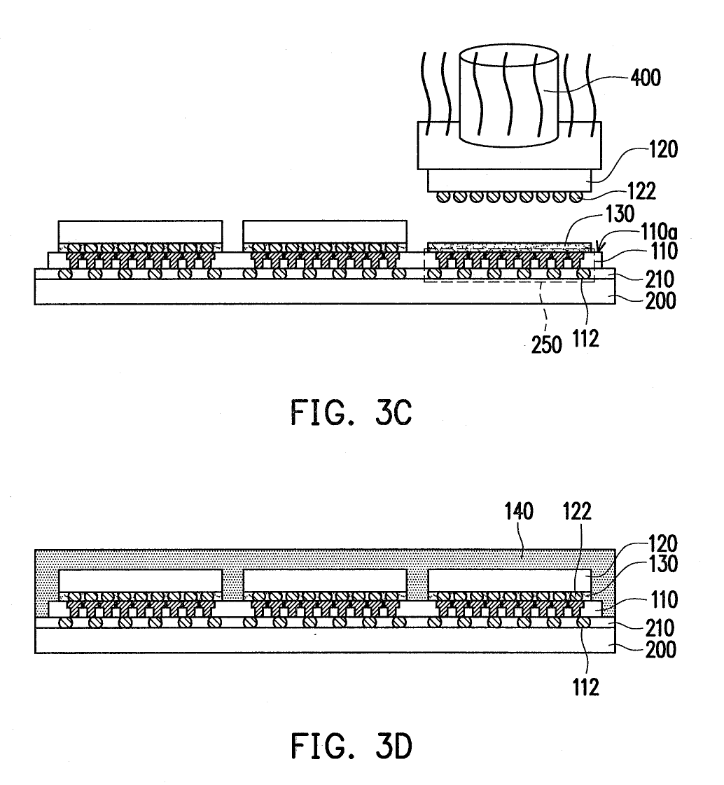

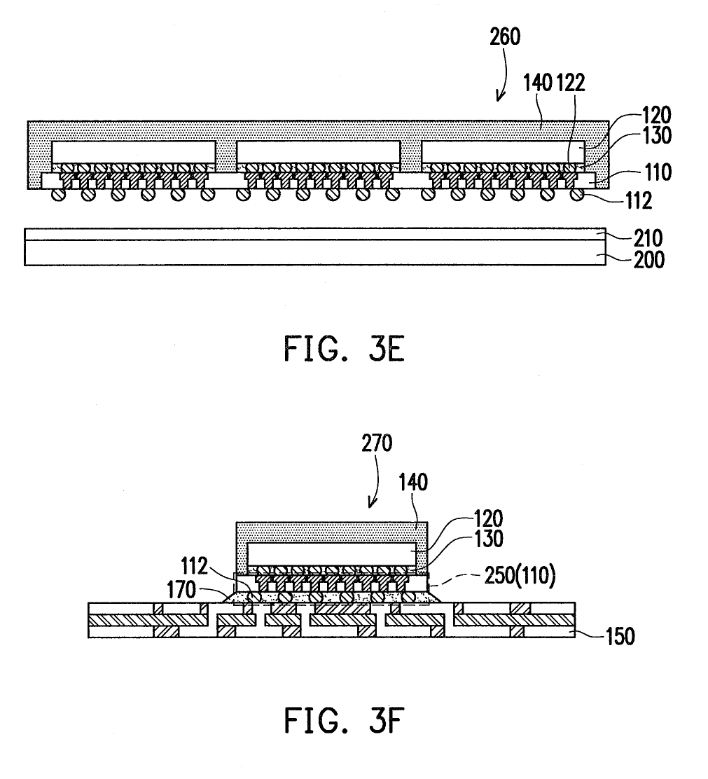

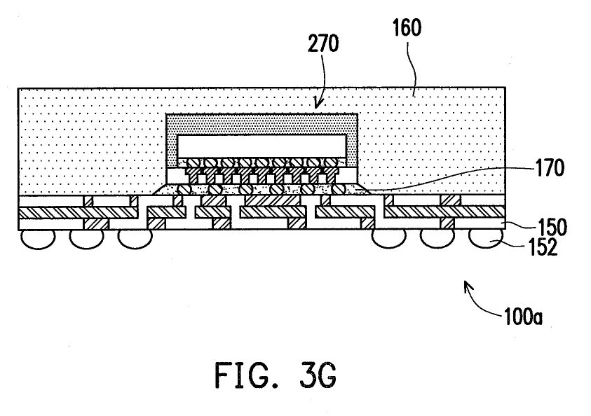

Furthermore, a package process of the aforementioned package structure is also provided in the present invention. FIG. 2 is a flow chart illustrating a manufacturing process of a package structure according to an embodiment of the present invention. FIGS. 3A through 3G are schematic cross-sectional views illustrating a package process according to an embodiment of the present invention.

Firstly, as illustrated in step S601 and FIG. 3A, a semiconductor substrate 110 is disposed on a carrier 200. A surface of the carrier 200 has an adhesive layer 210. The semiconductor substrate 110 is bonded to the carrier 200 by the adhesive layer 210. Here, the semiconductor substrate 110 is a silicon substrate, for instance.

In the present embodiment, the adhesive layer 210 is formed by coating on the carrier 200 through spin coating, for example. Moreover, before the semiconductor substrate 110 is disposed on the adhesive layer 210, an opening (not shown) with high aspect ratio is further formed in the semiconductor substrate 110, and a conductive material (not shown) is filled into the opening. Next, the semiconductor substrate 110 is disposed on the adhesive layer 210 and an upper surface 110a of the semiconductor substrate 110 is ground, so that a thickness of the semiconductor substrate 110 is reduced to under 8 mils, such as under 4 mils, or even 2 mils to thin the semiconductor substrate 110 and expose the conductive material in the opening. This opening and the conductive material within the opening constitute a TSV structure 114.

Thereafter, as illustrated in step S602 and FIGS. 3B and 3C, a first underfill 130 is formed between the chip 120 and the semiconductor substrate 110 through an injector 300. The chip 120 is bonded on the semiconductor substrate 110 by the flip chip technique through a thermal pressing head 400. Herein, the first underfill 130 encapsulates a plurality of first conductive bumps 122 at a bottom of the chip 120 to protect an electrical connection between the first conductive bumps 122 of the chip 120 and the TSV structure 114 of the semiconductor substrate 110 and prevent damages caused by moisture invasion.

Specifically, in the present embodiment, if a size of the chip 120 is closer to a size of a substrate unit 250 corresponding to the chip 120 on the semiconductor substrate 110, for example, a ratio of the size of the chip 120 and the size of the substrate unit 250 is between 95% to 100%, then after the chip 120 is flip chip bonded to the semiconductor substrate 110, a distance between two adjacent chips 120 is smaller. Thus, as shown in FIG. 3B, after the first underfill 130 is formed on the semiconductor substrate 110, the chip 120 is bonded to the semiconductor substrate 110 as illustrated in FIG. 3C, so that the first underfill 130 encapsulates the first conductive bumps 122 of the chip 120.

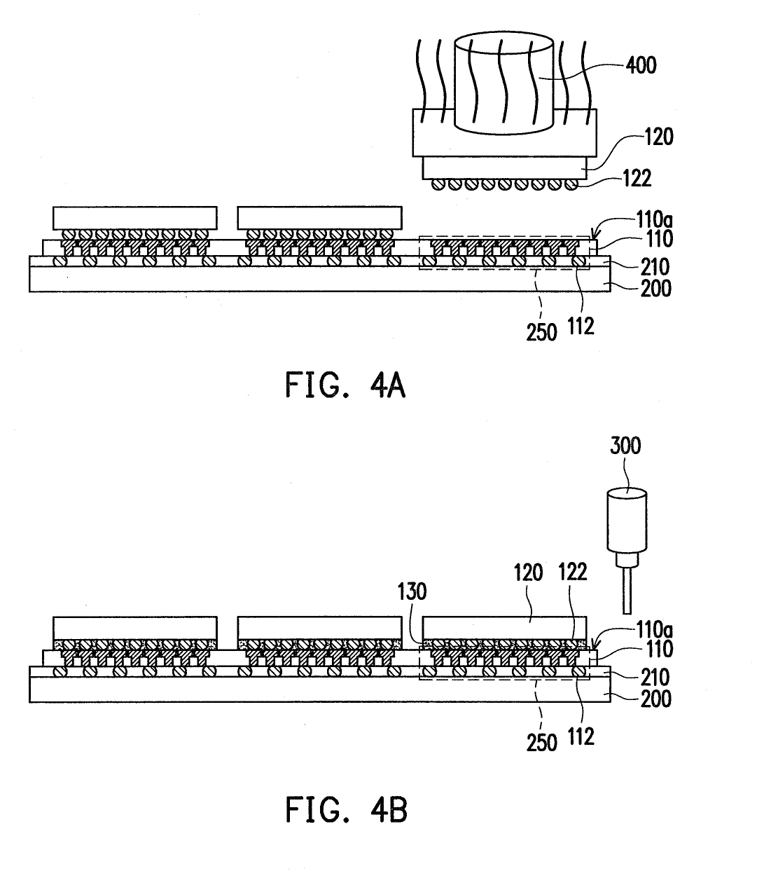

In another embodiment, if the size of the chip 120 and the size of a substrate unit 250 corresponding to the chip 120 on the semiconductor substrate 110 have a greater difference, for instance, the ratio of the size of the chip 120 and the size of the substrate unit 250 is smaller than or equal to 95%, then after the chip 120 is flip chip bonded to the semiconductor substrate 110, the distance between two adjacent chips 120 is greater. Therefore, steps in FIG. 3B and FIG. 3C are adopted optionally. Alternatively, as illustrated in FIG. 4A, after the chip 120 is bonded on the semiconductor substrate 110, the first underfill 130 is filled between the semiconductor substrate 110 and the chip 120 as illustrated in FIG. 4B to encapsulate the first conductive bumps 122 of the chip 120. In other words, the step of forming the first underfill 130 and bonding the chip 120 is optionally adjusted according to the size ratio of the chip 120 and a substrate unit 250 on the semiconductor substrate 110. The above illustration is merely exemplary, and the present embodiment is not limited thereto.

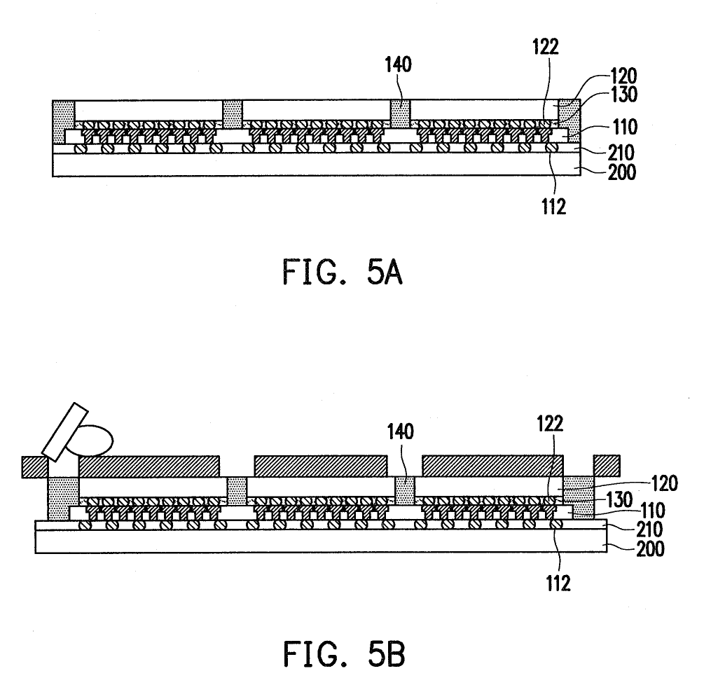

Afterwards, as illustrated in step S603 and FIG. 3D, a first molding compound 140 is formed on the semiconductor substrate 110. The first molding compound 140 at least encapsulates a side surface of the chip 120 and the first underfill 130. In the present embodiment, a method of forming the first molding compound 140 on the semiconductor substrate 110 is molding, for instance. The first molding compound 140 encapsulates a side surface of the chip 120, the first underfill 130, and a top surface of the chip 120 through molding. In another embodiment, as illustrated in FIG. 5A, the first molding compound 140 also encapsulates the side surface of the chip 120 and the first underfill 130 through molding. However, the first molding compound 140 exposes the top surface of the chip 120 to enhance the heat dissipation area and performance of the chip 120.

Obviously, the method of forming the first molding compound 140 on the semiconductor substrate 110 also includes other methods, such as printing. Referring to FIG. 5B, the first molding compound 140 encapsulates the side surface of the chip 120 and the first underfill 130 by printing through a screen 500. In other words, the first molding compound 140 does not encapsulate the top surface of the chip 120. That is, the first molding compound 140 exposes the top surface of the chip 120 to enhance the heat dissipation area and performance of the chip 120.

Later, as shown in step S604 and FIG. 3E, the semiconductor substrate 110 together with the chip 120 and the first molding compound 140 located thereon are separated from the adhesive layer 210 on the carrier 200 to form an array package structure 260. In the present embodiment, the semiconductor substrate 110 together with the chip 120 and the first molding compound 140 located thereon are separated from the adhesive layer 210 on the carrier 200 by heating and pressuring, thereby exposing a plurality of second conductive bumps 112 at the bottom of the semiconductor substrate 110.

Next, as illustrated in step S605 and FIG. 3F, the array package structure 260 is cut to form a plurality of chip package units 270 (only one is illustrated in FIG. 3F for representation). The chip package unit 270 includes the chip 120 and a substrate unit 250 corresponding to the chip 120 on the semiconductor substrate 110. In the present embodiment, in the method of cutting the array package structure 260, the first package compound 140 and the semiconductor substrate 110 are cut, so that the side of the first molding compound 140 substantially aligns with the side of the semiconductor substrate 110 to form the chip package unit 270.

Thereafter, as illustrated in steps S606-S607 and FIG. 3G, the chip package unit 270 is flip chip bonded on a circuit substrate 150. Moreover, a second molding compound 160 is formed on the circuit substrate 150 and a plurality of solder balls 152 is formed at a bottom of the circuit substrate 150. The second molding compound 160 encapsulates the side surface and the top surface of the chip package unit 270.

In details, in the present embodiment, before the second molding compound 160 is formed on the circuit substrate 150, a second underfill 170 is first formed between the chip package unit 270 and the circuit substrate 150 to encapsulate the second conductive bumps 112 at a bottom of the chip package unit 270. In the present embodiment, the circuit substrate 150 is a printed circuit board PCB. So far, the manufacture of the package structure 100a FIG. 1A is substantially completed.

Similarly, the second molding compound 160 also adopts the same package type as the first molding compound 140. That is, when the semiconductor substrate 110 in FIG. 5A adopts molding or when the semiconductor substrate 110 in FIG. 5B adopts printing so that the first molding compound 140 encapsulates thereon, and after the steps in FIG. 3E and FIG. 3F have been performed, the second molding compound 160 encapsulates the side surfaces of the first molding compound 140 and of the semiconductor substrate 110, and the top surfaces of the chip 120 and of the first molding compound 140 to complete the manufacture of the package structure 100b (referring to FIG. 1B). Alternatively, the second molding compound 160 merely encapsulates the side surfaces of the first molding compound 140 and of the semiconductor substrate 110. That is, the second molding compound 160 exposes the top surfaces of the first molding compound 140 and of the chip 120 to complete the manufacture of the package structure 100c (referring to FIG. 1C).

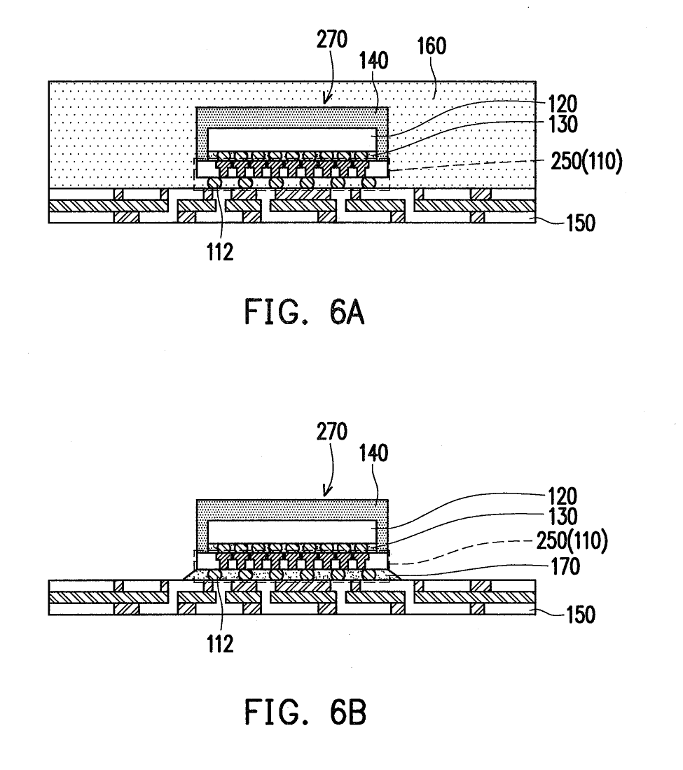

It should be illustrated that the present invention does not limit an order of bonding the chip package unit 270 on the circuit substrate 150 and forming the second underfill 170. In the present embodiment, the chip package unit 270 is first bonded to the circuit substrate 150 and the second underfill 170 is filled between the circuit substrate 150 and the chip package unit 270. However, in other embodiments, the second underfill 170 is first formed on the circuit substrate 150 and the chip package unit 270 is bonded on the circuit substrate 150, so that the second underfill 170 encapsulates the second conductive bumps 112. Obviously, in other embodiments, the second underfill 170 can also be absent. In other words, after the chip package unit 270 is bonded to the circuit substrate 150, the second molding compound 160 is directly formed to encapsulate the side surface and the top surface of the chip package unit 270. At this time, the second molding compound 160 also encapsulates the second conductive bumps 112 at the bottom of the chip package unit 270 (referring to FIG. 6A). Furthermore, in another embodiment, the second underfill 170 is present while the second molding compound 160 is absent. That is, only the second underfill 170 encapsulates the second conductive bumps 112, and the side surface and the top surface of the chip package unit 270 are not encapsulated by the second molding compound 160 (referring to FIG. 6B). In other words, the second underfill 170 is optionally filled between the chip package unit 270 and the circuit substrate 150. The second molding compound 160 optionally encapsulates the chip package unit 270.

In short, since the thickness of the semiconductor substrate 110 in the present embodiment is reduced to under 8 mils, such as under 4 mils or even 2 mils by grinding, when the chip 120 is bonded on the semiconductor substrate 110 by the flip chip technique, encapsulated by the first molding compound 140, and cut to form the chip package unit 270, this chip package unit 270 has a thinner package thickness. In addition, when this chip package unit 270 is bonded to the circuit substrate 150 by the flip chip technique and encapsulated by the second molding compound 160 to form the package structure 100a (or the package structure 100b, 100c), this package structure 100a (or the package structure 100b, 100c) has a thinner package thickness. Further, as the semiconductor substrate 110 is supported by the carrier 200, a fracture of the semiconductor substrate 110 in the flip chip bonding of the chip 120 onto the semiconductor substrate 110 is prevented. Besides, since the semiconductor substrate 110 is first packaged by the first molding compound 140 and then cut, the strength of the semiconductor substrate 110 is relatively enhanced to prevent the fracture of the semiconductor substrate 110 so as to lower the difficulty in the subsequent process and facilitate in enhancing the production yield rate. Moreover, it is suitable for mass production.

In summary, since the thickness of the semiconductor substrate of the present invention is reduced to under 8 mils, such as under 4 mils or even 2 mils, when the chip and the circuit substrate are respectively disposed on the upper surface and the lower surface of the semiconductor substrate, and the chip, the semiconductor substrate, and the circuit substrate are encapsulated by the molding compound to form the package structure, this package structure has a thinner package thickness. Also, when the molding compound exposes the top surface of the chip, the heat dissipation area and performance of the chip are enhanced, so that the package structure has superior heat dissipation effect. Additionally, since the semiconductor substrate is first packaged by the molding compound and then cut, the strength of the semiconductor substrate is relatively enhanced to lower the difficulty in the subsequent process and facilitate in enhancing the production yield rate. Moreover, it is suitable for mass production.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A package process, comprising:
disposing a semiconductor substrate on a carrier, wherein a surface of the carrier has an adhesive layer and the semiconductor substrate is bonded to the carrier by the adhesive layer;
bonding a chip on the semiconductor substrate by a flip chip technique via a plurality of first conductive bumps at a bottom of the chip;
forming a first molding compound on the semiconductor substrate and the first molding compound at least encapsulating a side surface of the chip; and
separating the semiconductor substrate together with the chip and the first molding compound located thereon from the adhesive layer of the carrier to form an array package structure.

2. The package process as claimed in claim 1, further comprising after disposing the semiconductor substrate on the carrier, grinding the semiconductor substrate to reduce a thickness of the semiconductor substrate under 4 mils.

3. The package process as claimed in claim 1, wherein a first underfill is coated on the semiconductor substrate before bonding the chip on the semiconductor substrate to encapsulate the first conductive bumps at the bottom of the chip, and the first molding compound further encapsulates the first underfill.

4. The package process as claimed in claim 1, wherein a first underfill is filled between the chip and the semiconductor substrate after bonding the chip on the semiconductor substrate to encapsulate the first conductive bumps at the bottom of the chip, and the first molding compound further encapsulates the first underfill.

5. The package process as claimed in claim 1, wherein the first molding compound further encapsulates a top surface of the chip.

6. The package process as claimed in claim 1, wherein the first molding compound exposes the top surface of the chip.

7. The package process as claimed in claim 1, wherein after removing the carrier and the adhesive layer, further comprising:
cutting the array package structure to form a chip package unit, and the chip package unit comprises the chip and a substrate unit of the corresponding semiconductor substrate, wherein a side of the first molding compound substantially aligns with a side of the semiconductor substrate.

8. The package process as claimed in claim 7, further comprising bonding the chip package unit on a circuit substrate by the flip chip technique.

9. The package process as claimed in claim 8, further comprising forming a second molding compound on the circuit substrate and the second molding compound at least encapsulating a side surface of the chip package unit.

10. The package process as claimed in claim 8, further comprising forming a second underfill between the chip package unit and the circuit substrate to encapsulate a plurality of second conductive bumps at a bottom of the chip package unit.

11. The package process as claimed in claim 9, wherein the second molding compound further encapsulates a top surface of the chip package unit.

12. The package process as claimed in claim 9, wherein the second molding compound further exposes the top surface of the chip package unit.

13. A package structure, comprising:
a semiconductor substrate having an upper surface, wherein a thickness of the semiconductor substrate is under 8 mils;
a chip, disposed on the upper surface of the semiconductor substrate and a bottom thereof having a plurality of first conductive bumps;
a first underfill, disposed between the semiconductor substrate and the chip to encapsulate the plurality of first conductive bumps; and
a first molding compound, disposed on the semiconductor substrate and at least encapsulating a side surface of the chip and the first underfill.

14. The package structure as claimed in claim 13, wherein the thickness of the semiconductor substrate is under 4 mils.

15. The package structure as claimed in claim 13, wherein the first molding compound further encapsulates a top surface of the chip.

16. The package structure as claimed in claim 13, wherein the first molding compound exposes the top surface of the chip.

17. The package structure as claimed in claim 13, further comprising a circuit substrate, disposed on a lower surface of the semiconductor substrate relative to the upper surface.

18. The package structure as claimed in claim 17, further comprising a second molding compound, disposed on the circuit substrate and at least encapsulating the first molding compound and a side surface of the semiconductor substrate.

19. The package structure as claimed in claim 17, further comprising a second underfill, disposed between the semiconductor substrate and the circuit substrate to encapsulate a plurality of second conductive bumps on the lower surface of the semiconductor substrate.

20. The package structure as claimed in claim 19, wherein the second molding compound further encapsulates the chip and a top surface of the first molding compound.

21. The package structure as claimed in claim 19, wherein the second molding compound further exposes the chip and the top surface of the first molding compound.

22. The package structure as claimed in claim 13, wherein the semiconductor substrate is a silicon substrate.

23. The package structure as claimed in claim 13, wherein a side of the first molding compound substantially aligns with a side of the semiconductor substrate.
